(19) United States
(12) Patent Application Publication
(10) Pub. No.: US 2026/0063996 A1
(43) Pub. Date: Mar. 5, 2026

(54) PHOTOSENSITIVE RESIN COMPOSITION, PHOTOSENSITIVE RESIN LAYER AND SEMICONDUCTOR DEVICE USING THE SAME

(71) Applicant: SAMSUNG SDI CO., LTD., Yongin-si (KR)

(72) Inventors: Heekyoung KANG, Suwon-si (KR); Sang Soo KIM, Suwon-si (KR); Taek-Jin BAEK, Suwon-si (KR); Chungbeum HONG, Suwon-si (KR); Jiyu KIM, Suwon-si (KR); Jinhee KANG, Suwon-si (KR); Hokyun RYU, Suwon-si (KR); Byeongwook PARK, Suwon-si (KR); Mingyum KIM, Suwon-si (KR)

(21) Appl. No.: 19/036,826

(22) Filed: Jan. 24, 2025

(30) Foreign Application Priority Data
Sep. 3, 2024 (KR) 10-2024-0119483

(51) Int. Cl. G03F 7/038; G03F 7/004

(52) U.S. Cl. CPC G03F 7/038; G03F 7/0045; G03F 7/0048

(57) ABSTRACT

Provided are a photosensitive resin composition, a photosensitive resin layer manufactured using the same, and a semiconductor device including the photosensitive resin layer, the photosensitive resin composition including a resin, wherein the resin includes a polymer represented by Chemical Formula 1. In Chemical Formula 1, each substituent is as defined in the specification.

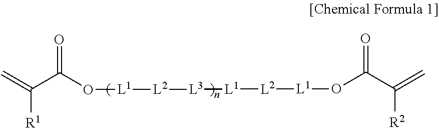

### CROSS-REFERENCE TO RELATED APPLICATION

The present application claims priority to and the benefit of Korean Patent Application No. 10-2024-0119483 filed in the Korean Intellectual Property Office on Sep. 3, 2024, the entire content of which is hereby incorporated by reference.

### BACKGROUND

### 1. Field

Embodiments of this disclosure relate to a photosensitive resin composition, a photosensitive resin layer using the same, and a semiconductor device.

### 2. Description of the Related Art

With the advent of an era of hyper-connected intelligence such as artificial intelligence, big data, Internet of Things (IoT) devices, self-driving cars, remote medical treatment, and the like, development and distribution of various electronic devices such as smartphones are being accelerated.

Accordingly, 5G communication technology capable of wirelessly transmitting ultra-high-speed and large-capacity data has become significantly more important, and in addition, a market size for communication component materials and component elements used in communication devices including smart phones is expected to substantially exponentially grow from 2020 to 2026 and reach approximately US $2.3 billion (about 14,000 tons/year).

A dielectric substrate used in frequency (Sub-6 and 28 GHz) bands for 5G communication, in order to minimize or reduce a propagation loss, has low permittivity (Dk) and a low dielectric loss factor (Df), which may not be satisfied by polyimide (PI), which is mainly used for conventional 4G LTE communication. Ming-Chi Kuo, an analyst at TF International, expected in 2018 “modified polyimide (MPI) to replace a liquid crystal polymer (LCP) as a mainstream antenna technology for new iPhone model in the second half of the year,” which means that as a FCCL (Flexible Cupper Clad Laminate) manufacturing process was structured with a production line of using a polyimide film (an existing process), because module manufacturers would prefer to perform the existing process rather than modifying the equipment to a LCP-using process, he hoped that MPI (Modified PI) would be quickly developed and applied. This suggests that MPI to complement the drawbacks of LCP has already been being developed.

In other words, the interest in developing a polyimide precursor resin having low permittivity (Dk) and a low dielectric loss factor (Df) has recently been rapidly increasing.

### SUMMARY

Some example embodiments provide a photosensitive resin composition including a resin having excellent reliability and low dielectric loss factor (Df).

Some example embodiments provide a photosensitive resin layer manufactured using the photosensitive resin composition.

Some example embodiments provide a semiconductor device including the photosensitive resin layer.

Some example embodiments provide a photosensitive resin composition including a resin, wherein the resin includes a polymer represented by Chemical Formula 1.

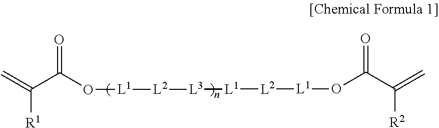

In Chemical Formula 1,
R¹ and R² are each independently a hydrogen atom or a substituted or unsubstituted C1 to C20 alkyl group,
L¹ is a single bond (e.g., a single covalent bond) or a substituted or unsubstituted C1 to C20 alkylene group,
L² is a divalent linking group derived from an acid anhydride,
L³ is a divalent linking group including an ester linkage (*—C(═O)O—* or *—OC(═O)—*), and
n is an integer from 1 to 50.

In Chemical Formula 1, L² may be represented by Chemical Formula 2-1 or Chemical Formula 2-2.

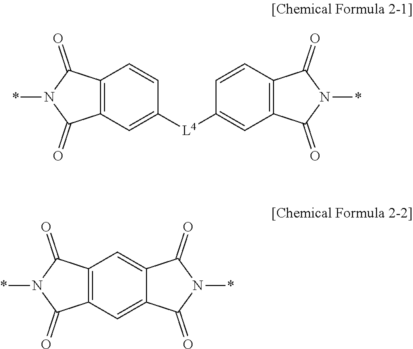

In Chemical Formula 2-1,
L⁴ is a single bond (e.g., a single covalent bond), an ether linking group (*—O—*), or a substituted or unsubstituted C1 to C20 alkylene group.

In Chemical Formula 1, L³ may be a divalent linking group including two or more ester linking groups.

In Chemical Formula 1, L³ may be represented by Chemical Formula 3.

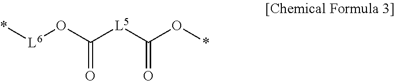

In Chemical Formula 3,
L⁵ is an ether linking group (*—O—*) or a substituted or unsubstituted C1 to C20 alkylene group, and
L⁶ is a substituted or unsubstituted C1 to C10 alkylene group.

The polymer represented by Chemical Formula 1 may be represented by any one of Chemical Formula 1-1 to Chemical Formula 1-4.

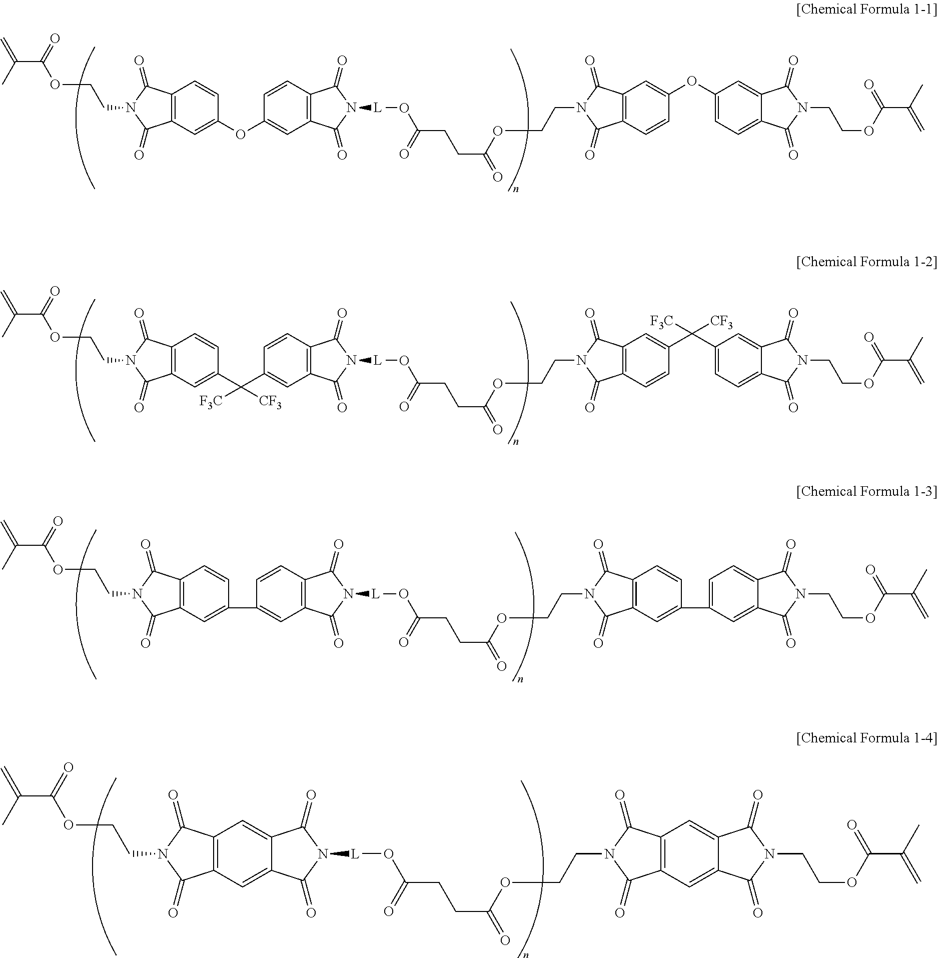

In Chemical Formula 1-1 to Chemical Formula 1-4,
L is a substituted or unsubstituted C1 to C10 alkylene group, and
n is an integer from 1 to 50.

The resin further may further include a polymer produced by a polymerization reaction of a diamine compound and a dianhydride compound, and the polymer produced by the polymerization reaction of the diamine compound and the dianhydride compound may have a different structure from the polymer represented by Chemical Formula 1.

The diamine compound may be represented by Chemical Formula 4.

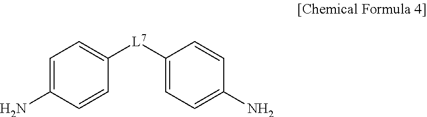

In Chemical Formula 4,
L⁷ is *—O—*, *—S—*, *—C≡C—*, *—C(═O)—*, *—NR⁰—* (R⁰ is a substituted or unsubstituted C1 to C10 alkyl group), or a combination thereof.

The dianhydride compound may be represented by Chemical Formula 5.

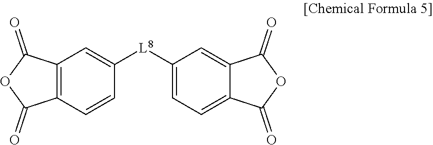

In Chemical Formula 5,
L⁸ is a single bond (e.g., a single covalent bond), *—O—*, *—S—*, *—C≡C—*, *—C(═O)—*, *—C(═O)O—*, *—NR⁰—* (R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

The polymer represented by Chemical Formula 1 and the polymer produced by the polymerization reaction of the diamine compound and the dianhydride compound may be included in a weight ratio of about 50:50 to about 90:10.

The photosensitive resin composition may further include a photopolymerizable compound, a photopolymerization initiator, and a solvent.

The photosensitive resin composition may include the photopolymerizable compound in an amount of about 5 to about 20 parts by weight, the photopolymerization initiator in an amount of about 0.1 to about 20 parts by weight, and the solvent in an amount of about 100 to about 500 parts by weight, based on 100 parts by weight of the resin.

The photosensitive resin composition may further include an additive selected from diacid, alkanolamine, a leveling agent, a silane coupling agent, a surfactant, an epoxy compound, a thermal latent acid generator, a sensitizer, a radical scavenger, an adhesive, organic acid, or a combination thereof.

The photosensitive resin composition may be a negative type (or kind of) photosensitive resin composition.

The photosensitive resin composition may have a dielectric loss factor (Df) of about 0.001 to about 0.015 at a frequency of 10 GHz.

Some example embodiments provide a photosensitive resin layer manufactured using the photosensitive resin composition.

Some example embodiments provide a semiconductor device including the photosensitive resin layer.

Other embodiments are included in the following detailed description.

According to some example embodiments, a polymer having a set or specific structure included in a resin in a photosensitive resin composition includes (meth)acrylate groups at both terminal ends, facilitating formation of a negative pattern, and further includes an ester linkage between the two terminal ends, enabling securing low dielectric loss characteristics.

### DETAILED DESCRIPTION

Hereinafter, embodiments are described in more detail. However, these embodiments are examples, and this disclosure is not limited thereto.

As used herein, when specific definition is not otherwise provided, “alkyl group” refers to a C1 to C20 alkyl group, “alkenyl group” refers to a C2 to C20 alkenyl group, “cycloalkenyl group” refers to a C3 to C20 cycloalkenyl group, “heterocycloalkenyl group” refers to a C3 to C20 heterocycloalkenyl group, “aryl group” refers to a C6 to C20 aryl group, “arylalkyl group” refers to a C7 to C20 arylalkyl group, “alkylene group” refers to a C1 to C20 alkylene group, “arylene group” refers to a C6 to C20 arylene group, “alkylarylene group” refers to a C7 to C20 alkylarylene group, “heteroarylene group” refers to a C3 to C20 heteroarylene group, and “alkoxylene group” refers to a C1 to C20 alkoxylene group.

As used herein, when specific definition is not otherwise provided, “substituted” refers to replacement of at least one hydrogen of a compound by a substituent selected from a halogen atom (F, Cl, Br, or I), a C1 to C20 alkyl group substituted with a halogen atom such as a trifluoromethyl group, a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, a (meth)acrylate group, or a combination thereof.

As used herein, when specific definition is not otherwise provided, “hetero” refers to inclusion of at least one heteroatom of N, O, S, and P, in the chemical formula.

As used herein, when specific definition is not otherwise provided, “(meth)acrylate” refers to both “acrylate” and “methacrylate.”

As used herein, when a definition is not otherwise provided, the term “combination” refers to mixing or copolymerization. Also, “copolymerization” means block copolymerization, alternating copolymerization, or random copolymerization, and “copolymer” means a block copolymer, an alternating copolymer, or a random copolymer.

As used herein, when specific definition is not otherwise provided, an unsaturated bond includes not only multiple bonds between carbon and carbon atoms (e.g., a double bond or a triple bond between two carbon atoms), but also those containing other molecules, moieties, or bonds, such as, for example, a carbonyl bond and an azo bond.

In the chemical formula of the present specification, unless a specific definition is otherwise provided, hydrogen is bonded at the position when a chemical bond is not drawn where supposed to be given.

As used herein, when a definition is not otherwise provided, “*” refers to a linking part between the same or different atoms, or chemical formulas.

A photosensitive resin composition according to some example embodiments includes a resin including a polymer represented by Chemical Formula 1.

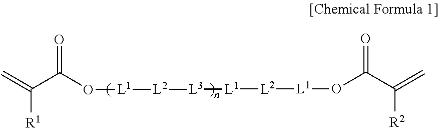

In Chemical Formula 1,
R¹ and R² are each independently a hydrogen atom or a substituted or unsubstituted C1 to C20 alkyl group,
L¹ is a single bond (e.g., a single covalent bond) or a substituted or unsubstituted C1 to C20 alkylene group,
L² is a divalent linking group derived from an acid anhydride,
L³ is a divalent linking group including an ester linkage (*—C(═O)O—* or *—OC(═O)—*), and
n is an integer from 1 to 50.

In order to secure low permittivity (Dk) and a low dielectric loss factor (Df), there have been many attempts to polymerize various types (or kinds) of polyimide precursor resins, and as a result, it is currently believed that the higher content of fluorine atoms in molecules constituting the resins and the lower content of imide structures, the easier to secure the low permittivity (Dk) and low dielectric loss factor (Df).

However, as semiconductor technology has advanced, a chip size has decreased, which has led to an interest in replacing an existing positive type (or kind of) polyimide precursor resin, which is not well cured at a low temperature and lacks of pattern formability, with a negative type (or kind of) polyimide precursor resin.

Accordingly, the present inventors invented a structure for securing low permittivity (Dk) and a low dielectric loss factor (Df) of the negative type (or kind of) polyimide precursor resin (or a negative type (or kind of) resin) rather than the existing positive type (or kind of) polyimide precursor resin and furthermore, confirmed that permittivity and a dielectric loss factor of the negative type (or kind of) polyimide precursor resin (or negative type (or kind of) resin) may not only be kept to be low, for example, a dielectric loss factor (Df) of about 0.001 to about 0.015 at a frequency of about 10 GHz but also reliability may be improved due to easy negative pattern formability, thereby completing the subject matter of the present disclosure.

Hereinafter, each component is described in more detail.

### (A) Resin

In order to secure film characteristics such as elongation and a glass transition temperature (Tg), which are important for reliability as elements of a photosensitive resin composition used for a semiconductor circuit protection film, a polyimide (PI) and/or polybenzoxazole (PBO) resin is used. A photosensitive resin composition including the resin also includes a photocross-linking monomer, a photopolymerization initiator, and/or the like to secure excellent protective layer characteristics and should leave no (or substantially no) residue to implement excellent patterns, excellent sensitivity characteristics, and storage stability at room temperature for about 2 weeks or more. In embodiments, when high frequencies must be used to improve a processing speed of an electronic device, in order to prevent or reduce a transmission speed loss, a material having low permittivity (Dk) and a dielectric loss factor (Df) is utilized.

The resin used in the photosensitive resin composition according to some example embodiments may be a negative type (or kind of) resin, for example, a polyimide precursor resin, for example, a polyamic acid and/or polyamic ester-based resin, wherein the polyamic acid and/or polyamic ester-based resin may include a diamine compound and a polymer produced through a polymerization reaction of the dianhydride compound but is not necessarily limited thereto.

The negative type (or kind of) resin includes a polymer represented by Chemical Formula 1, which is confirmed to have lower permittivity (Dk) and a dielectric loss factor (Df) of the negative type (or kind of) photosensitive resin composition at high frequencies.

For example, in Chemical Formula 1, L² may be represented by Chemical Formula 2-1 or Chemical Formula 2-2.

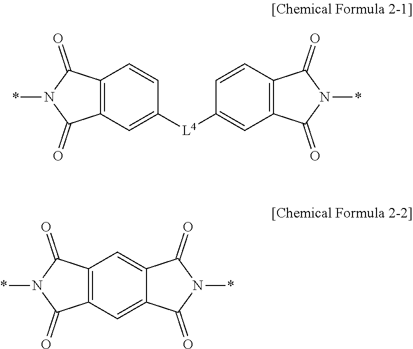

In Chemical Formula 2-1,
L⁴ is a single bond (e.g., a single covalent bond), an ether linking group (*—O—*), or a substituted or unsubstituted C1 to C20 alkylene group.

For example, in Chemical Formula 2-1, L⁴ may be a single bond (e.g., a single covalent bond) or a substituted or unsubstituted C1 to C20 alkylene group.

For example, in Chemical Formula 2-1, L⁴ may be a C1 to C20 alkylene group substituted or unsubstituted with a halogen group. For example, the halogen group may be a fluoro group.

For example, in Chemical Formula 1, L³ may be a divalent linking group including two or more ester linking groups. In embodiments, the implementation of low dielectric loss characteristics may be more advantageous compared to when including one ester linking group.

For example, in Chemical Formula 1 above, L³ may be represented by Chemical Formula 3, but is not necessarily limited thereto.

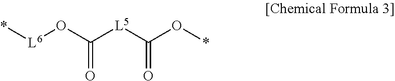

In Chemical Formula 3,
L⁵ is an ether linking group (*—O—*) or a substituted or unsubstituted C1 to C20 alkylene group, and
L⁶ is a substituted or unsubstituted C1 to C10 alkylene group.

Even if a cured layer (e.g., an electrically insulating layer, resin layer) is manufactured using a negative type (or kind of) photosensitive resin composition having a low dielectric loss factor, if (e.g., when) its physical properties such as adhesion to a metal layer, reliability such as heat resistance, and/or the like are inferior, it may be difficult to apply it to a semiconductor device. However, because the photosensitive resin composition according to one embodiment includes a polymer having a structure represented by Chemical Formula 1 as a component, it can have a low dielectric loss factor and excellent reliability despite being a negative type (or kind of) composition.

For example, the polymer represented by Chemical Formula 1 may be represented by any one of Chemical Formula 1-1 to Chemical Formula 1-4, but is not necessarily limited thereto.

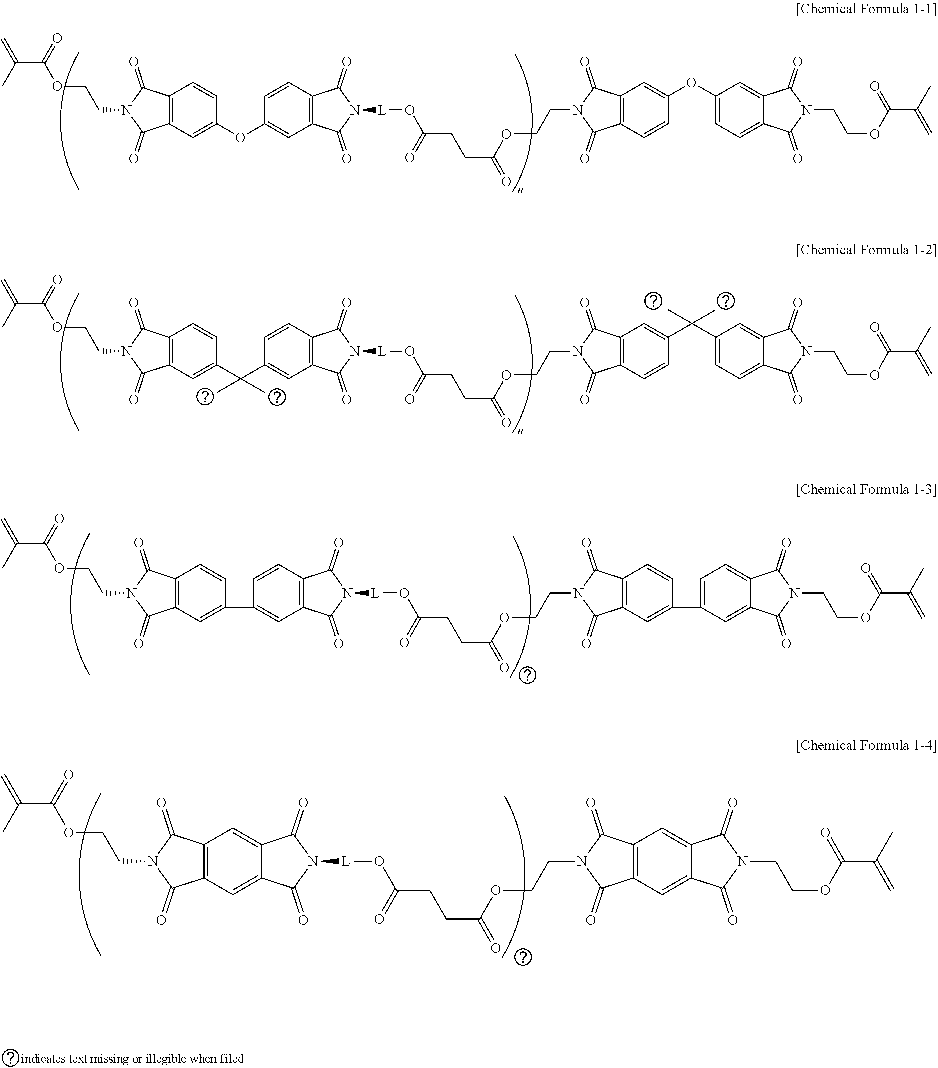

In Chemical Formula 1-1 to Chemical Formula 1-4,
L is a substituted or unsubstituted C1 to C10 alkylene group, and
n is an integer from 1 to 50.

In embodiments, the resin may further include another polymer having a different structure from the polymer represented by Chemical Formula 1. In embodiments, the other polymer may be a polymer produced by a polymerization reaction of a diamine compound and a dianhydride compound. In embodiments, it is possible to improve the elongation (e.g., of the resin) while maintaining the low dielectric loss characteristics.

For example, the polymer produced by the polymerization reaction of the diamine compound and the dianhydride compound may include a functional group represented by Chemical Formula 6.

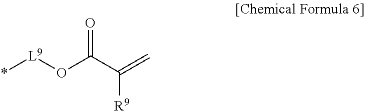

In Chemical Formula 6,
R⁹ is a hydrogen atom or a substituted or unsubstituted C1 to C10 alkyl group, and
L⁹ is a single bond (e.g., a single covalent bond) or a substituted or unsubstituted C1 to C10 alkylene group.

For example, the polymer represented by Chemical Formula 1 and the polymer produced by the polymerization reaction of the diamine compound and the dianhydride compound may be included in a weight ratio of about 50:50 to about 90:10. In embodiments, the increase in the dielectric loss factor of the photosensitive resin composition may be suppressed or reduced while at the same time improving the elongation (e.g., of the resin) to a greater or even the greatest extent.

For example, the diamine compound may be represented by Chemical Formula 4, but is not necessarily limited thereto.

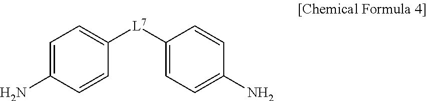

In Chemical Formula 4,
L⁷ is *—O—*, *—S—*, *—C≡C—*, *—C(═O)—*, *—NR⁰—* (R⁰ is a substituted or unsubstituted C1 to C10 alkyl group) or a combination thereof.

For example, the dianhydride compound may be represented by Chemical Formula 5, but is not necessarily limited thereto.

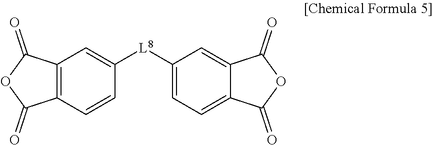

In Chemical Formula 5,
L⁸ is a single bond (e.g., a single covalent bond), *—O—*, *—S—*, *—C≡C—*, *—C(═O)—*, *—C(═O)O—*, *—NR⁰—* (R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

For example, when L⁸ is *—C≡C—*, the heat resistance, adhesion, and reliability of the cured layer (e.g., electrical insulation layer, resin film) may be further improved.

For example, the dianhydride compound may be, but is not necessarily limited to, pyromellitic dianhydride, 3,3′,4,4′-biphenyltetracarboxylic dianhydride, 4,4′-oxydiphthalic anhydride, 4,4′-hexafluoroisopropylidene)diphthalic anhydride, and/or the like.

A weight average molecular weight (Mw) of the polymer represented by Chemical Formula 1 may be about 3,000 g/mol to about 300,000 g/mol. In embodiments, suitable or sufficient physical properties can be obtained, and the solubility in organic solvents is excellent, making handling easy.

### (B) Photopolymerizable Compound

The photosensitive resin composition according to some example embodiments may further include a photopolymerizable compound. The photopolymerizable compound may be a single compound or a mixture of two different compounds.

The photopolymerizable compound may be a compound including at least two functional groups represented by Chemical Formula 6.

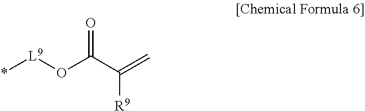

In Chemical Formula 6,
R⁹ is a hydrogen atom or a substituted or unsubstituted C1 to C10 alkyl group, and
L⁹ is a single bond (e.g., a single covalent bond) or a substituted or unsubstituted C1 to C10 alkylene group.

For example, the compound including at least two functional groups represented by Chemical Formula 6 may include two to six functional groups represented by Chemical Formula 4. In embodiments, suitable or sufficient polymerization can be induced during exposure in the pattern formation process to form a pattern having excellent heat resistance, light resistance, and chemical resistance.

For example, the compound including at least two functional groups represented by Chemical Formula 6 may be a compound represented by any one of Chemical Formula 7 to Chemical Formula 9, but is not necessarily limited thereto.

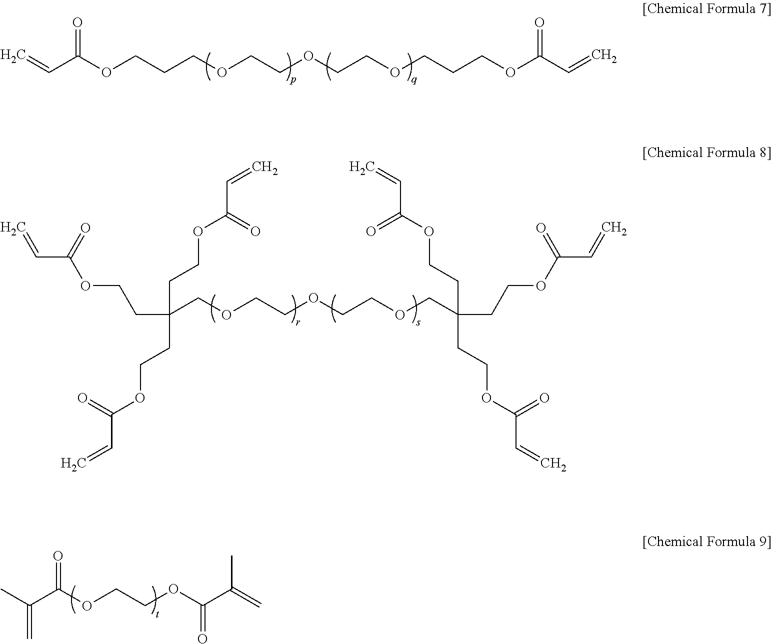

In Chemical Formula 7 to Chemical Formula 9,
p, q, r, s, and t are each independently an integer of 1 to 10.

When the photopolymerizable compound is a mixture of two different compounds, the other one of the two compounds may be a mono- or multi-functional ester compound of (meth)acrylic acid having at least one ethylenically unsaturated double bond.

The mono- or multi-functional ester compound of (meth)acrylic acid having at least one ethylenically unsaturated double bond may be for example, ethylene glycoldi(meth)acrylate, diethylene glycoldi(meth)acrylate, triethylene glycoldi(meth)acrylate, propylene glycoldi(meth)acrylate, neopentylglycoldi(meth)acrylate, 1,4-butanedioldi(meth)acrylate, 1,6-hexanedioldi(meth)acrylate, bisphenol A di(meth)acrylate, pentaerythritoldi(meth)acrylate, pentaerythritoltri(meth)acrylate, pentaerythritoltetra(meth)acrylate, pentaerythritolhexa(meth)acrylate, dipentaerythritoldi(meth)acrylate, dipentaerythritoltri(meth)acrylate, dipentaerythritolpenta(meth)acrylate, dipentaerythritolhexa(meth)acrylate, bisphenol A epoxy(meth)acrylate, ethylene glycolmonomethylether (meth)acrylate, trimethylolpropanetri(meth)acrylate, tris(meth)acryloyloxyethylphosphate, novolac epoxy (meth)acrylate, or a combination thereof.

Commercially available products of the monofunctional or multifunctional ester compound of (meth)acrylic acid having at least one ethylenically unsaturated double bond may be as follows. Examples of the mono-functional ester of (meth)acrylic acid may include Aronix M-101©, M-111 ©, M-114© (Toagosei Chemistry Industry Co., Ltd.); KAYARAD TC-110S©, TC-120S© (Nippon Kayaku Co., Ltd.); V-158©, V-2311©(Osaka Organic Chemical Ind., Ltd.), and the like. Examples of a di-functional ester of (meth)acrylic acid may include Aronix M-210©, M-240©, M-6200© (Toagosei Chemistry Industry Co., Ltd.), KAYARAD HDDA©, HX-220©, R-604© (Nippon Kayaku Co., Ltd.), V-260©, V-312©, V-335 HP© (Osaka Organic Chemical Ind., Ltd.), and the like. Examples of a tri-functional ester of (meth)acrylic acid may include Aronix M-309©, M-400©, M-405©, M-450©, M-7100©, M-8030©, M-8060© (Toagosei Chemistry Industry Co., Ltd.), KAYARAD TMPTA©, KAYARAD DPCA-20©, KAYARAD DPCA-30©, KAYARAD DPCA-60©, KAYARAD DPCA-120© (Nippon Kayaku Co., Ltd.), V-295©, V-300©, V-360©, V-GPT©, V-3PA©, V-400© (Osaka Yuki Kayaku Kogyo Co. Ltd.), and the like. These may be used alone or as a mixture of two or more.

The photopolymerizable compound may be used after being treated with an acid anhydride to provide better developability.

The photopolymerizable compound may be included in an amount of about 5 parts by weight to about 20 parts by weight or, for example about 7 parts by weight to about 15 parts by weight, based on 100 parts by weight of the resin. If the photopolymerizable compound is included within the above ranges, curing occurs suitably or sufficiently, reliability is excellent, heat resistance, light resistance, and chemical resistance of the pattern are improved, and resolution and adhesion are also improved.

### (C) Photopolymerization Initiator

The photosensitive resin composition according to some example embodiments may further include a photopolymerization initiator. The photopolymerization initiator may be an acetophenone-based compound, a benzophenone-based compound, a thioxanthone-based compound, a benzoin-based compound, a triazine-based compound, an oxime-based compound, and/or the like.

Examples of the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloroacetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone-based compound may be thioxanthone, 2-chlorothioxanthone, 2-methylthioxanthone, isopropyl thioxanthone, 2,4-diethyl thioxanthone, 2,4-diisopropyl thioxanthone, and the like.

Examples of the benzoin-based compound may be benzoin, benzoin methyl ether, benzoin ethyl ether, benzoin isopropyl ether, benzoin isobutyl ether, benzyl dimethyl ketal, and the like.

Examples of the triazine-based compound may be 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compounds may include an O-acyloxime compound, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl]ethanone, O-ethoxycarbonyl-a-oxyamino-1-phenylpropan-1-one, and the like. Specific examples of the O-acyloxime compounds may include 1,2-octanedione, 2-dimethylamino-2-(4-methylbenzyl)-1-(4-morpholin-4-yl-phenyl)-butan-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octane-1-one oxime-O-acetate, and 1-(4-phenylsulfanylphenyl)-butane-1-one oxime-O-acetate.

The photopolymerization initiator may include a carbazole-based compound, a diketone-based compound, a sulfonium borate-based compound, a diazo-based compound, an imidazole-based compound, a biimidazole-based compound, and/or a fluorene-based compound, in addition to the above compounds.

The photopolymerization initiator may be included in an amount of about 0.1 to about 20 parts by weight, for example, about 1 to about 10 parts by weight or, for example, about 1 to about 7 parts by weight, based on 100 parts by weight of the resin.

When the photopolymerization initiator is included within the above ranges, photopolymerization occurs suitably or sufficiently, resulting in excellent sensitivity and improved transmittance (e.g., light transmittance).

### (D) Solvent

The solvent may be a material that is compatible with, but does not react with, the resin, the photopolymerizable compound, and the photopolymerization initiator.

Examples of the solvent may include alcohols such as methanol, ethanol, and the like; ethers such as dichloroethylether, n-butylether, diisoamylether, methylphenylether, tetrahydrofuran, and the like; glycolethers such as ethylene glycolmonomethylether, ethylene glycolmonoethylether, ethylene glycoldimethylether, and the like; cellosolveacetates such as methylcellosolveacetate, ethylcellosolveacetate, diethylcellosolveacetate, and the like; carbitols such as methylethylcarbitol, diethylcarbitol, diethylene glycolmonomethylether, diethylene glycolmonoethylether, diethylene glycoldimethylether, diethylene glycolethylmethylether, diethylene glycoldiethylether, and the like; propylene glycolalkyletheracetates such as propylene glycolmethyletheracetate, propylene glycolpropyletheracetate, and the like; aromatic hydrocarbons such as toluene, xylene, and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, oxy butyl acetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxypropionic acid alkyl esters such as 3-oxymethyl propionate, 3-oxyethyl propionate, and the like; 3-alkoxypropionic acid alkyl esters such as 3-methoxymethyl propionate, 3-methoxyethyl propionate, 3-ethoxyethyl propionate, 3-ethoxymethyl propionate, and the like; 2-oxypropionic acid alkyl esters such as 2-oxymethyl propionate, 2-oxyethyl propionate, 2-oxypropyl propionate, and the like; 2-alkoxypropionic acid alkyl esters such as 2-methoxymethyl propionate, 2-methoxyethyl propionate, 2-ethoxyethyl propionate, 2-ethoxymethyl propionate, and the like; 2-oxy-2-methylpropionic acid esters such as 2-oxy-2-methylmethyl propionate, 2-oxy-2-methylethyl propionate, and the like, monooxy monocarboxylic acid alkyl esters of 2-alkoxy-2-methyl alkyl propionates such as 2-methoxy-2-methylmethyl propionate, 2-ethoxy-2-methylethyl propionate, and the like; esters such as 2-hydroxyethyl propionate, 2-hydroxy-2-methylethyl propionate, hydroxy ethyl acetate, 2-hydroxy-3-methyl methyl butanoate, and the like; ketonate esters such as ethyl pyruvate, and the like. In embodiments, a high boiling point solvent such as N-methylformamide, N,N-dimethyl formamide, N-methylformanilide, N-methylacetamide, N,N-dimethyl acetamide, N-methylpyrrolidone, dimethylsulfoxide, benzylethylether, dihexylether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, 3-methyl benzoate, ethylene carbonate, propylene carbonate, phenyl cellosolve acetate, and/or the like may be also used.

The solvent may be included in an amount of about 100 to about 500 parts by weight based on 100 parts by weight of the resin. If the solvent is included within the above range, the photosensitive resin composition has suitable or appropriate viscosity, resulting in excellent processability when manufacturing photosensitive resin layers.

### (E) Other Additives

The photosensitive resin composition according to some example embodiments may further include other additives.

The photosensitive resin composition may include additives such as diacid (e.g., malonic acid, and/or the like), alkanolamine (e.g., 3-amino-1,2-propanediol, N-phenyldiethanolamine, and/or the like), a leveling agent, a silane coupling agent, a surfactant, an epoxy compound, a thermal latent acid generator, a development controlling agent, a curing agent, a sensitizer, a radical scavenger, an adhesive, organic acid, or a combination thereof, and/or the like, to prevent or reduce stains and/or spots during coating, to provide leveling properties, and/or to prevent or reduce the creation of residues due to non-development. An amount of these additives used can be easily adjusted depending on suitable or desired physical properties.

For example, the silane coupling agent may have a reactive substituent such as a vinyl group, carboxyl group, methacryloxy group, isocyanate group, and/or epoxy group to improve adhesion to the substrate, and has a different structure from the silane compound.

Examples of the silane coupling agent may include trimethoxysilylbenzoic acid, γ-methacryloxypropyltrimethoxysilane, vinyltriacetoxysilane, vinyltrimethoxysilane, γ-isocyanatepropyltriethoxysilane, γ-glycidoxypropyltrimethoxysilane, p-(3,4-epoxycyclohexyl)ethyltrimethoxysilane, and the like. These may be used alone or in a mixture of two or more.

The silane coupling agent may be included in an amount of about 0.01 parts by weight to about 10 parts by weight based on 100 parts by weight of the photosensitive resin composition. If the silane coupling agent is included within the above range, adhesion, storage properties, and the like are improved.

For example, the surfactant may be added to prevent or reduce film thickness unevenness and/or improve developability, and may include a fluorine-based surfactant and/or a silicone-based surfactant.

Examples of the fluorine-based surfactant may be a commercial fluorine-based surfactant such as BM-1000©, BM-1100©, and the like of BM Chemie Inc.; MEGAFACE F 142D©, MEGAFACE F 172©, MEGAFACE F 173©, MEGAFACE F 183©, MEGAFACE F 554©, and the like of Dainippon Ink Kagaku Kogyo Co., Ltd.; FLUORAD FC-135©, FLUORAD FC-170C©, FLUORAD FC-430©, FLUORAD FC-431©, and the like of SUMITOMO 3M Co., Ltd.; SURFLON S-112©, SURFLON S-113©, SURFLON S-131©, SURFLON S-141©, SURFLON S-145©, and the like of Asahi Glass Co., Ltd.; SH-28PA©, SH-190©, SH-193©, SZ-6032©, SF-8428©, and the like of, Toray Silicone Co., Ltd.

The silicone-based surfactant may be a commercial silicone-based surfactant such as BYK-307, BYK-333, BYK-361 N, BYK-051, BYK-052, BYK-053, BYK-067A, BYK-077, BYK-301, BYK-322, BYK-325, BYK-378, and the like of BYK Chem.

The surfactant may be used in an amount of about 0.001 parts by weight to about 5 parts by weight based on 100 parts by weight of the photosensitive resin composition. If the surfactant is included within the above range, coating uniformity can be ensured or improved, stains cannot occur, and wetting on indium tin oxide (ITO) substrates and/or glass substrates, Si wafers and/or SiNₓ wafers, and Cu substrates can be improved.

In embodiments, the photosensitive resin composition further includes an epoxy compound to improve adhesion and the like with a substrate. Examples of the epoxy compound may include a phenol novolac epoxy compound, a tetramethyl biphenyl epoxy compound, a bisphenol A epoxy compound, an alicyclic epoxy compound, or a combination thereof.

The epoxy compound may be used in an amount of about 0.01 part by weight to about 5 parts by weight based on 100 parts by weight of the resin composition. When the epoxy compound is included within the above range, storage properties, adhesive force, and other properties can be improved.

In embodiments, the photosensitive resin composition may further include a thermal latent acid generator. Examples of the thermal latent acid generator may include arylsulfonic acids such as p-toluenesulfonic acid and benzenesulfonic acid; perfluoroalkylsulfonic acids such as trifluoromethanesulfonic acid, trifluorobutanesulfonic acid, and/or the like; alkylsulfonic acids such as methanesulfonic acid, ethanesulfonic acid, butanesulfonic acid, and/or the like; or a combination thereof, but is not limited thereto.

In embodiments, the photosensitive resin composition may further include an organic acid, such as citric acid, to improve low dielectric loss characteristics.

Furthermore, the photosensitive resin composition may include other additives such as an antioxidant, a stabilizer, and/or the like in a set or predetermined amount unless they deteriorate properties of the photosensitive resin composition.

Some example embodiments provide a photosensitive resin layer manufactured by exposing, developing, and curing the photosensitive resin composition described herein.

The photosensitive resin layer may be, for example, a semiconductor redistribution layer insulating layer, but is not necessarily limited thereto, and any suitable cured layer applicable to electronic devices may be used.

The photosensitive resin layer manufacturing method may be as follows.

### (1) Coating and Film Formation

The photosensitive resin composition is coated to have a suitable or desired thickness on a substrate such as a glass substrate and/or ITO substrate, Si wafer and/or SiNx wafer, Cu substrate, and/or the like which undergoes a set or predetermined pretreatment, using a spin and/or slit coating method, a roll coating method, a screen-printing method, an applicator method, and/or the like, and is heated at about 70° C. to about 150° C. for about 1 minute to 10 minutes to remove a solvent and thereby to form a film.

### (2) Exposure

After providing a mask to form a desired or necessary pattern on the obtained photosensitive resin layer, exposure is performed by irradiating an actinic ray of 200 nm to 500 nm. As a light source used for irradiation, a low-pressure mercury lamp, a high-pressure mercury lamp, an ultra-high pressure mercury lamp, a metal halide lamp, an argon gas laser, and/or the like may be used, and in some cases, an X-ray, an electron beam, and/or the like may be used.

The exposure dose may suitably vary depending on the type (or kind of), mixing amount, and dry film thickness of each component of the composition, but is less than 500 mJ/cm² (based on a 365 nm sensor) when using a high-pressure mercury lamp.

### (3) Development

In the development method, following the exposure step, alkali aqueous solution or an organic solvent is used as a developer to dissolve and remove unnecessary parts, leaving only (or substantially only) the exposed parts remaining to form a pattern.

### (4) Post-Processing

There may be a post-heating process to obtain a pattern excellent in terms of heat resistance, light resistance, adhesion, crack resistance, chemical resistance, high strength, and storage stability of the image pattern obtained by development in the above process. For example, after development, it can be heated in a nitrogen atmosphere in an oven at about 200° C. to about 400° C. for 1 hour or more.

Some example embodiments provide an electronic device including the photosensitive resin layer.

The electronic device may be, for example, a semiconductor device, but is not necessarily limited thereto.

Hereinafter, examples of the present disclosure will be further described. However, the following examples are only embodiments of the present disclosure, and the present disclosure is not limited by the following examples.

### EXAMPLES

### Synthesis of Resin

### Comparative Synthesis Example 1

18.98 g (65 mmol) of 3,3,4,4-biphenyltetracarboxylic dianhydride (BPDA), 17.72 g (136 mmol) of methacrylic acid-2-hydroxyethyl (HEMA), and a catalyst amount of DBU (1,8-diazabicyclo[5.4.0]undeca-7-ene) were dissolved in N-methyl-2-pyrrolidone, whose amount was 4 times that of the pyromellitic acid dianhydride, and then, stirred at room temperature for 48 hours to obtain Ester solution 1.

In addition, 46.35 g (149 mmol) of 4,4′-oxydiphthalic anhydride (ODPA), 42 g (323 mmol) of methacrylic acid 2-hydroxyethyl (HEMA), and a catalyst amount of DBU were dissolved in N-methyl-2-pyrrolidone, whose amount was 4 times that of the 4,4′-oxydiphthalic anhydride (ODPA), and then, stirred at room temperature for 48 hours to obtain Ester solution 2. After mixing Ester solution 1 and Ester solution 2, while cooling the mixture in an ice bath, 2.2 equivalents of thionyl chloride based on a total amount of the BPDA-HEMA ester solution and the ODPA-HEMA ester solution was added dropwise thereto and then, stirred for 1 hour to prepare an acid chloride solution.

Subsequently, 4,4′-oxydianiline (ODA) (100 mmol) and pyridine, whose amount was twice the equivalent of thionyl chloride, were dissolved in N-methyl-2-pyrrolidone, whose amount was 4 times that of ODA, to prepare a solution, which was added dropwise to the acid chloride solution, while cooling in the ice bath. After completing the dropwise addition, the resultant reaction solution was added dropwise to distilled water to form precipitates, and the precipitates were separated through filtration, gathered, twice washed with distilled water, and vacuum-dried to obtain polyamide acid ester. The obtained polymer (polyamide acid ester) had a weight average molecular weight of 25000 g/mol.

### Synthesis Example 1

While passing nitrogen through a four-necked flask equipped with a stirrer, a temperature controller, a nitrogen gas injection device, and a condenser, 0.58 mol of a 4,4′-oxydiphthalic anhydride (ODPA) monomer was added to 600 g of γ-butyrolactone (GBL), and then, 1.22 mol of 2-hydroxyethylmethacrylate (HEMA) was added thereto, and while stirring the mixture at room temperature, 1.16 mol of pyridine was added thereto to obtain a reaction mixture. After reacting the reaction mixture at room temperature for 16 hours and cooling it to −10° C., a solution prepared by dissolving 250 g of GBL in 1.17 mol of dicyclohexylcarbodiimide (DCC) was added dropwise thereto over 30 minutes. After additionally stirring for 5 minutes, a solution of 0.54 mol of a diamine monomer represented by Chemical Formula B and 300 g of GBL was added thereto for 40 minutes and then, additionally stirred for 2 hours.

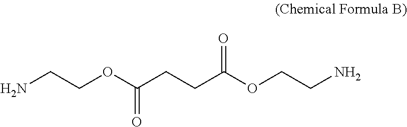 [SMILES: NCCOC(=O)CCC(=O)OCCN]

Subsequently, after reacting at a room temperature for 1 hour, 30 g of a monomer represented by Chemical Formula C was added thereto and then, stirred for 1 hour.

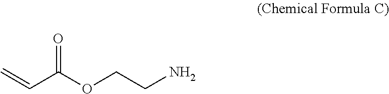

Subsequently, GBL was added to the reaction solution to have a solid content of 18% and then, added to 3 liters of ethanol to obtain precipitates. A polymer was separated therefrom through filtration, dissolved in 1.5 liters of tetrahydrofuran (THF), and then, added in a dropwise fashion to 30 liters of water to form precipitates, and the precipitates were separated through filtration and vacuum-dried. The obtained precipitates were dried at 50° C. under a reduced pressure for 24 hours or more to prepare the polymer (a weight average molecular weight: 22,000 g/mol) represented by Chemical Formula 1-1 (L=an unsubstituted ethylene group).

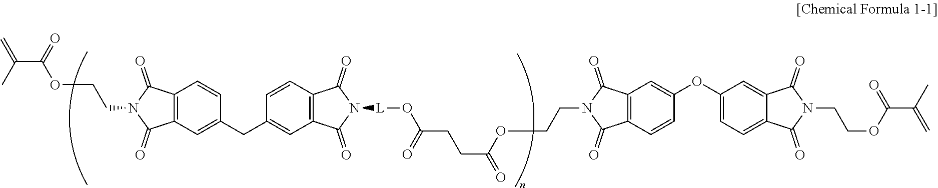

### Synthesis Example 2

A polymer (a weight average molecular weight: 22,000 g/mol) represented by Chemical Formula 1-2 (L=an unsubstituted ethylene group) was obtained in substantially the same manner as in Synthesis Example 1 except that 4,4′-(hexafluoroisopropylidene)diphthalic anhydride (6FDA) was used instead of the 4,4′-oxydiphthalic anhydride (ODPA) monomer of Synthesis Example 1.

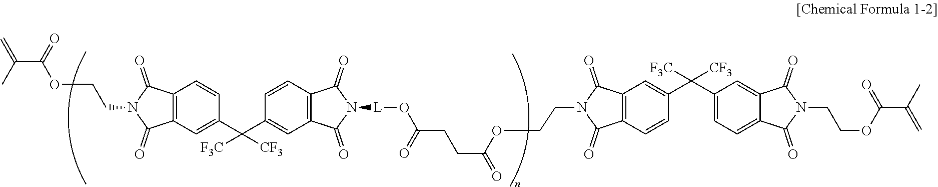

### Synthesis Example 3

A polymer (a weight average molecular weight: 22,000 g/mol) represented by Chemical Formula 1-3 (L=an unsubstituted ethylene group) was obtained in substantially the same manner as in Synthesis Example 1 except that 3,3,4,4-Biphenyltetracarboxylic dianhydride (BPDA) was used instead of the 4,4′-oxydiphthalic anhydride (ODPA) monomer of Synthesis Example 1.

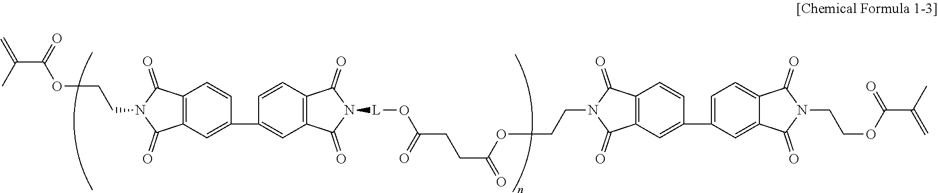

### Synthesis Example 4

A polymer (having a weight average molecular weight: 22,000 g/mol) represented by Chemical Formula 1-4 (L=an unsubstituted ethylene group) was obtained in substantially the same manner as in Synthesis Example 1 except that pyromellitic dianhydride was used instead of the 4,4′-oxydiphthalic anhydride (ODPA) monomer of Synthesis Example 1.

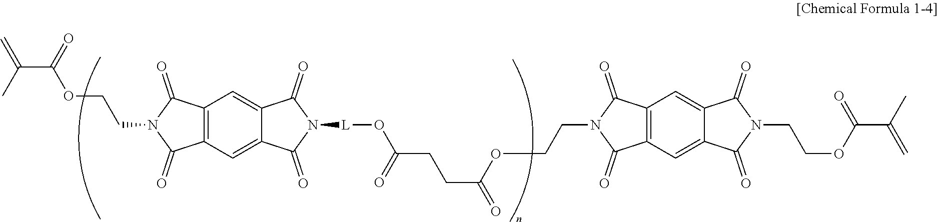

### Preparation of Photosensitive Resin Composition

### Comparative Example 1

33.28 g of the polymer according to Comparative Synthesis Example 1 was mixed with 3.69 g of tetraethylene glycol dimethacrylate, and then, 1.66 g of a photo polymerization initiator (PBG305, TRONLY), 3.32 g of a sensitizer (N-phenyldiethanolamine), 0.55 g of a radical scavenger (CX-1790), 0.92 g of an adhesion promoter A-187, 0.18 g of citric acid, 50.76 g of GBL, and 5.64 g of DMSO were added thereto and then, sufficiently stirred. Subsequently, a negative type (or kind of) photosensitive resin composition was obtained by filtering through a 0.45 μm polypropylene resin filter.

### Example 1

A photosensitive resin composition was obtained in substantially the same manner as in Comparative Example 1 except that a mixture of 16.64 g of the polymer according to Comparative Synthesis Example 1 and 16.64 g of the polymer according to Synthesis Example 1 (in a weight ratio of 50:50) was used instead of 33.28 g of the polymer according to Comparative Synthesis Example 1.

### Example 2

A photosensitive resin composition was obtained in substantially the same manner as in Comparative Example 1 except that a mixture of 3.328 g of the polymer according to Comparative Synthesis Example 1 and 29.952 g of the polymer according to Synthesis Example 1 (in a weight ratio of 10:90) was used instead of 33.28 g of the polymer according to Comparative Synthesis Example 1.

### Example 3

A photosensitive resin composition was obtained in substantially the same manner as in Comparative Example 1 except that the polymer of Synthesis Example 1 was used instead of the polymer according to Comparative Synthesis Example 1.

### Example 4

A photosensitive resin composition was obtained in substantially the same manner as in Comparative Example 1 except that a mixture of 16.64 g of the polymer according to Comparative Synthesis Example 1 and 16.64 g of the polymer according to Synthesis Example 2 (in a weight ratio of 50:50) was used instead of 33.28 g of the polymer according to Comparative Synthesis Example 1.

### Example 5

A photosensitive resin composition was obtained in substantially the same manner as in Comparative Example 1 except that a mixture of 16.64 g of the polymer according to Comparative Synthesis Example 1 and 16.64 g of the polymer according to Synthesis Example 3 (in a weight ratio of 50:50) was used instead of 33.28 g of the polymer according to Comparative Synthesis Example 1.

### Example 6

A photosensitive resin composition was obtained in substantially the same manner as in Comparative Example 1 except that a mixture of 16.64 g of the polymer according to Comparative Synthesis Example 1 and 16.64 g of the polymer according to Synthesis Example 4 (in a weight ratio of 50:50) was used instead of 33.28 g of the polymer according to Comparative Synthesis Example 1.

### Example 7

A photosensitive resin composition was obtained in substantially the same manner as in Comparative Example 1 except that a mixture of 1.664 g of the polymer according to Comparative Synthesis Example 1 and 31.616 g of the polymer according to Synthesis Example 1 (in a weight ratio of 5:95) was used instead of 33.28 g of the polymer according to Comparative Synthesis Example 1.

### Example 8

A photosensitive resin composition was obtained in substantially the same manner as in Comparative Example 1 except that a mixture of 18.304 g of the polymer according to Comparative Synthesis Example 1 and 14.976 g of the polymer according to Synthesis Example 1 (in a weight ratio of 55:45) was used instead of 33.28 g of the polymer according to Comparative Synthesis Example 1.

### Evaluation

Each of the photosensitive resin compositions was spin-coated on an 8″ silicon wafer and then, pre-baked at about 100° C. for 4 minutes to obtain an about 10.0 μm-thick film. Then, after cooling at room temperature for 60 seconds, light at 700 milliseconds (msec) was irradiated with an i-line stepper (NSR-2005i10C, Nikon Inc.) thereto to induce a photocuring reaction in the photosensitive portion. The exposed substrate was twice developed with a 100% cyclopentanone solvent at room temperature for 60 seconds in a puddle method and then, washed with a 100% PGMEA solvent for 60 seconds. Subsequently, the developed wafer was cured in a 220° C. oven under a nitrogen atmosphere for 2 hours to obtain a photosensitive resin layer (film).

### (1) Dielectric Loss Factor Evaluation:

After pretreating the obtained films by drying at 130° C. for 30 minutes and aging them at 23° C. under relative humidity of 50% in a constant temperature and humidity chamber for 24 hours, the obtained films were evaluated with respect to a dielectric loss factor (Df). Subsequently, dielectric characteristics of the films were measured at a frequency of 10 GHz by using ENA made by Keysight in a Split Post Dielectric Resonator (SPDR) measurement method, and the results are shown in Table 1.

### (2) Elongation Evaluation:

After immersing the cured films in a 1% HF solution for 1 hour to prepare PID film specimens, each of the specimen was cut into 1 cm*10 cm and then measured with respect to elongation at room temperature (25° C.) by using a tensile tester (HZ-1003) made by Shimazu Corp., and the results are shown in Table 1.

### (3) Reliability Evaluation:

The cured films were subjected to 2000 thermal cycles (−55° C.-125° C.), to evaluate a reliability condition. Subsequently, whether or not cracks between the films with Cu occurred was checked by using FE-SEM, and the results are shown in Table 1.

TABLE 1

| | Comparative | | | | | | | | |
|---|---|---|---|---|---|---|---|---|---|
| | Example | Example | Example | Example | Example | Example | Example | Example | Example |
| | 1 | 1 | 2 | 3 | 4 | 5 | 6 | 7 | 8 |
| Df @ 10 GHz | 0.02 | 0.012 | 0.009 | 0.006 | 0.005 | 0.007 | 0.004 | 0.016 | 0.018 |
| Elongation (%) | 50 | 64 | 59 | 55 | 52 | 50 | 60 | 50 | 51 |
| Reliability | OK | OK | OK | OK | OK | OK | OK | OK | OK |

Referring to Table 1, the photosensitive resin composition according to some example embodiments exhibited a low dielectric loss factor and excellent elongation and reliability.

While the subject matter of this disclosure has been described in connection with what is presently considered to be practical example embodiments, it is to be understood that the present disclosure is not limited to the disclosed embodiments, but, on the contrary, is intended to cover various modifications and equivalent arrangements included within the spirit and scope of the appended claims, and equivalents thereof. Therefore, the aforementioned embodiments should be understood to be examples but not limiting the present disclosure in any way.

What is claimed is:

1. A photosensitive resin composition, comprising:
a resin,
wherein the resin comprises a polymer represented by Chemical Formula 1: 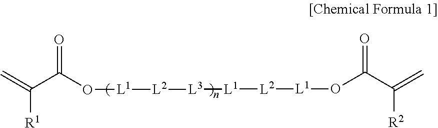
wherein in Chemical Formula 1,
R¹ and R² are each independently a hydrogen atom or a substituted or unsubstituted C1 to C20 alkyl group,
L¹ is a single bond or a substituted or unsubstituted C1 to C20 alkylene group,
L² is a divalent linking group derived from an acid anhydride,
L³ is a divalent linking group including an ester linkage (*—C(═O)O—* or *—OC(═O)—*), and
n is an integer from 1 to 50.

2. The photosensitive resin composition as claimed in claim 1, wherein:
L² is represented by Chemical Formula 2-1 or Chemical Formula 2-2: 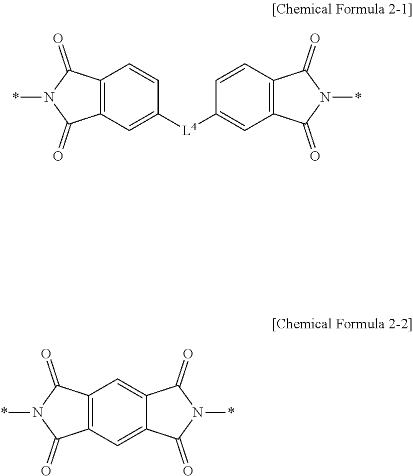
wherein in Chemical Formula 2-1,
L⁴ is a single bond, an ether linking group (*—O—*), or a substituted or unsubstituted C1 to C20 alkylene group.

3. The photosensitive resin composition as claimed in claim 1, wherein
L³ is a divalent linking group comprising two or more ester linking groups.

4. The photosensitive resin composition as claimed in claim 1, wherein:
L³ is represented by Chemical Formula 3: 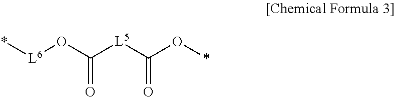
wherein in Chemical Formula 3,
L⁵ is an ether linking group (*—O—*) or a substituted or unsubstituted C1 to C20 alkylene group, and
L⁶ is a substituted or unsubstituted C1 to C10 alkylene group.

5. The photosensitive resin composition as claimed in claim 1, wherein:
the polymer represented by Chemical Formula 1 is represented by any one of Chemical Formula 1-1 to Chemical Formula 1-4, 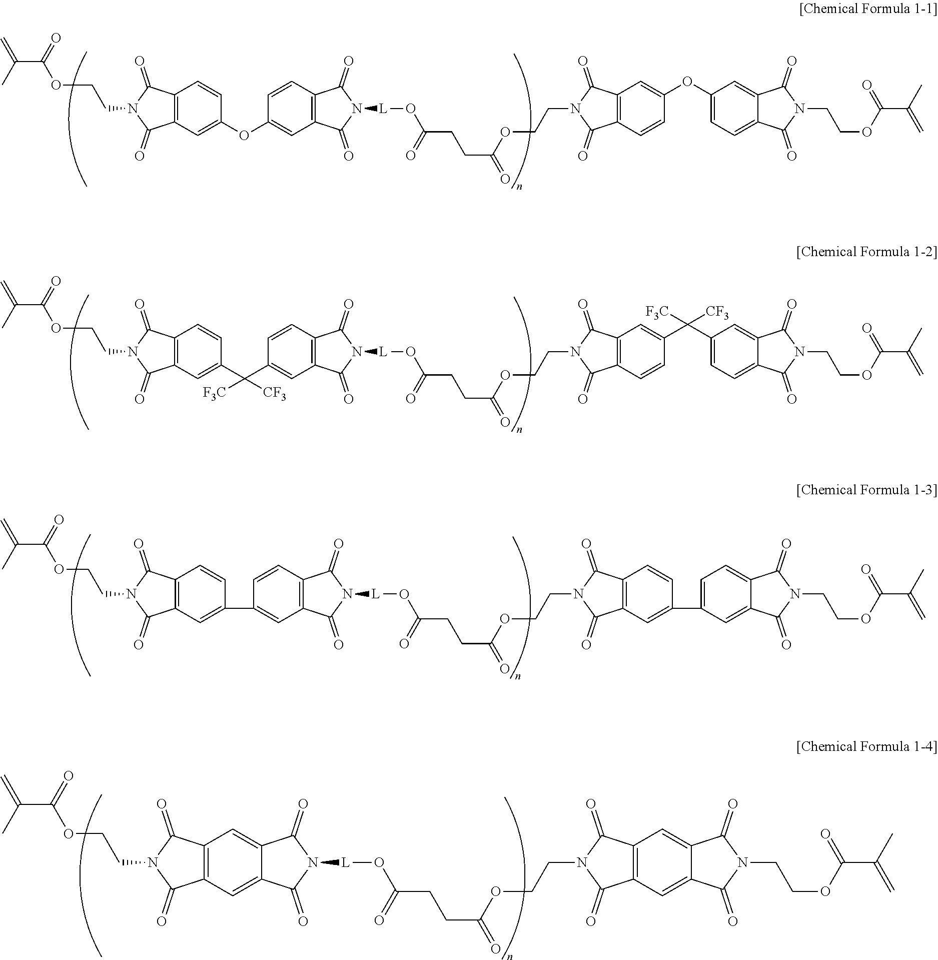
wherein in Chemical Formula 1-1 to Chemical Formula 1-4,
L is a substituted or unsubstituted C1 to C10 alkylene group, and
n is an integer from 1 to 50.

6. The photosensitive resin composition as claimed in claim 1, wherein:
the resin further comprises a polymer produced by a polymerization reaction of a diamine compound and a dianhydride compound, and
the polymer produced by the polymerization reaction of the diamine compound and the dianhydride compound has a different structure from the polymer represented by Chemical Formula 1.

7. The photosensitive resin composition as claimed in claim 6, wherein:
the diamine compound is represented by Chemical Formula 4: 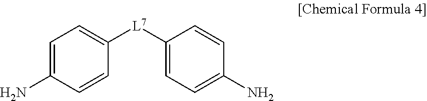
wherein in Chemical Formula 4,
L⁷ is *—O—*, *—S—*, *—C≡C—*, *—C(═O)—*, *—NR⁰—* (R⁰ is a substituted or unsubstituted C1 to C10 alkyl group) or a combination thereof.

8. The photosensitive resin composition as claimed in claim 6, wherein:
the dianhydride compound is represented by Chemical Formula 5: 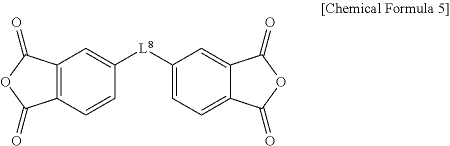
wherein in Chemical Formula 5,
L⁸ is a single bond, *—O—*, *—S—*, *—C≡C—*, *—C(═O)—*, *—C(═O)O—*, *—NR⁰—* (R⁰ is a substituted or unsubstituted C1 to C10 alkyl group), a substituted or unsubstituted C1 to C20 alkylene group, a substituted or unsubstituted C6 to C20 arylene group, a substituted or unsubstituted C2 to C20 heterocyclic linking group, or a combination thereof.

9. The photosensitive resin composition as claimed in claim 6, wherein:
the polymer represented by Chemical Formula 1 and the polymer produced by the polymerization reaction of the diamine compound and the dianhydride compound are included in a weight ratio of about 50:50 to about 90:10.

10. The photosensitive resin composition as claimed in claim 6, wherein:
the polymer produced by the polymerization reaction of the diamine compound and the dianhydride compound comprises a functional group represented by Chemical Formula 6: 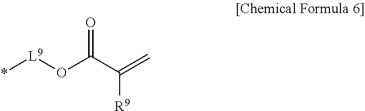
wherein in Chemical Formula 6,
R⁹ is a hydrogen atom or a substituted or unsubstituted C1 to C10 alkyl group, and
L⁹ is a single bond or a substituted or unsubstituted C1 to C10 alkylene group.

11. The photosensitive resin composition as claimed in claim 1, wherein:
the photosensitive resin composition further comprises a photopolymerizable compound, a photopolymerization initiator, and a solvent.

12. The photosensitive resin composition as claimed in claim 11, wherein:
the photosensitive resin composition comprises,
based on 100 parts by weight of the resin,
about 5 parts by weight to about 20 parts by weight of the photopolymerizable compound,
about 0.1 parts by weight to about 20 parts by weight of the photopolymerization initiator, and
about 100 parts by weight to about 500 parts by weight of the solvent.

13. The photosensitive resin composition as claimed in claim 1, wherein:
the photosensitive resin composition is a negative type photosensitive resin composition.

14. The photosensitive resin composition as claimed in claim 1, wherein:
the photosensitive resin composition has a dielectric loss factor (Df) of about 0.001 to about 0.015 at a frequency of 10 GHz.

15. A photosensitive resin layer manufactured using the photosensitive resin composition as claimed in claim 1.

16. A semiconductor device comprising the photosensitive resin layer as claimed in claim 15.
